(19) United States
(12) Patent Application Publication
(10) Pub. No.: US 2025/0185189 A1
(43) Pub. Date: Jun. 5, 2025

(54) DISPLAY DEVICE

(71) Applicant: LG ELECTRONICS INC., Seoul (KR)

(72) Inventors: Seunggyu KANG, Seoul (KR); Jonggil PYO, Seoul (KR); Byunghee KIM, Seoul (KR)

(73) Assignee: LG ELECTRONICS INC., Seoul (KR)

(21) Appl. No.: 18/842,013

(22) PCT Filed: Mar. 28, 2022
(86) PCT No.: PCT/KR2022/004330

§ 371 Date: Aug. 27, 2024

(51) Int. Cl. H05K 5/02

(52) U.S. Cl. CPC H05K 5/0217

(57) ABSTRACT

Provided is a display device comprising: a display module which outputs an image; a cover bottom which covers the rear surface of the display module; a printed circuit board which is disposed at the rear surface of the cover bottom; a moving bracket which is disposed at the rear surface of the cover bottom and has a variable-sized area exposed below the display module; and a drive unit which drives the moving bracket in the up-and-down direction, wherein the drive unit comprises: a motor which provides rotating power; and a rack gear which is moved in the up-and-down direction by the rotating power transmitted thereto from the motor and is fastened to the moving bracket.

### TECHNICAL FIELD

The present disclosure relates to a slim display device having improved wireless performance.

### BACKGROUND ART

With growth of information society, demand for various display devices has increased. In order to satisfy such demand, in recent years, a liquid crystal display (LCD), a field emission display (FED), a plasma display panel (PDP), and an electroluminescent device have been developed as display devices.

A liquid crystal panel of the liquid crystal display includes a liquid crystal layer and a TFT substrate and a color filter substrate opposite each other in the state in which the liquid crystal layer is interposed therebetween, wherein a picture is displayed using light provided from a backlight unit.

An active matrix type organic light-emitting display has come onto the market as an example of the electroluminescent device. Since the organic light-emitting display is self-emissive, the organic light-emitting display has no backlight, compared to the liquid crystal display, and has merits in terms of response time and viewing angle, and therefore the organic light-emitting display has attracted attention as a next-generation display.

Recently, a material such as OLED emits light on its own without a backlight structure on a rear surface, making it difficult to dispose a printed circuit board and the like as display devices with thinner thickness and minimal bezel size designs are developed, especially because antennas are affected by surrounding components.

### DISCLOSURE

### Technical Tasks

One technical task of the present disclosure is to provide a display device of a slim design.

### Technical Solutions

In one technical aspect of the present disclosure, provided is a display device including a display module outputting an image, a cover bottom covering a rear surface of the display module, a printed circuit board positioned on a rear surface of the cover bottom, a moving bracket positioned on the rear surface of the cover bottom and having a variable size of an area exposed under the display module, and a driving unit driving the moving bracket in a vertical direction, the driving unit including a motor providing a rotational force and a rack gear moving in the vertical direction by receiving the rotational force of the motor and fastened to the moving bracket.

An axis of the motor may be vertically disposed and the driving unit may include a first gear coupled to a rotational shaft of the motor, a second gear rotating by engaging with the first gear and having a horizontal direction as an axis, and a third gear rotating about the horizontal direction based on rotation of the second gear and rotating by engaging with the rack gear.

The first gear may include a worm shaft and the second gear may include a worm gear.

The display device may include a shaft member having the second gear positioned at one end portion thereof and the third gear positioned at the other side thereof, a first stepped portion may be formed at both sides of the third gear, and the rack gear may include a second stepped portion having a shape related to a stepped portion of the third gear.

The rack gear may include a pair of gear parts spaced apart from each other in the horizontal direction and a pair of the third gears may be provided to correspond to positions of the gear parts, respectively.

The rack gear may be coupled to a center of the moving bracket and the display device may further include vertical guides positioned at both sides of the moving bracket, respectively.

The display device o may include a controller configured to drive the motor to move the moving bracket downward based on turning on the display module.

The display device may further include an IR sensor sensing a remote control signal for turning on/off the display module, and the IR sensor may be disposed at a lower end portion of the moving bracket so as to be always exposed in a front direction.

The moving bracket may move between a first position and a second position, the moving bracket may further include a position sensor generating a braking signal by detecting whether at least one of the first position or the second position is reached, and the controller may stop driving the motor in response to the braking signal of the position sensor.

A diameter of the motor may be equal to or smaller than 10 mm.

The display device may include an antenna module mounted on the moving bracket.

### Advantageous Effects

A display device of the present disclosure may provide a bezel-less, slim-designed display device.

A display device of the present disclosure selectively exposes a configuration required for viewing a display device, such as an antenna or speaker, in a front direction, thereby maintaining a clean appearance in normal times.

Effects obtainable from the present disclosure are not limited by the above mentioned effects, and other unmentioned effects can be clearly understood from the above description by those having ordinary skill in the technical field to which the present disclosure pertains.

### DESCRIPTION OF DRAWINGS

FIG. 1 is a block diagram illustrating components of a display device according to the present disclosure.

FIG. 2 is a perspective view showing an example of the display device according to the present disclosure.

FIG. 3 and FIG. 4 are diagrams illustrating front and rear surfaces of a display device in an OFF state and an ON state according to the present disclosure, respectively.

FIG. 5 is a front perspective diagram illustrating a first state of a driving unit and a moving bracket of a display device of the present disclosure.

FIG. 6 is a rear perspective diagram illustrating a first state of a driving unit and a moving bracket of a display device of the present disclosure.

FIG. 7 is a rear perspective diagram illustrating a second state of a driving unit and a moving bracket of a display device according to the present disclosure.

FIG. 8 is a diagram illustrating a side view of a display device of the present disclosure.

FIG. 9 is a diagram illustrating a disposition example of an IR sensor and a moving bracket of the present disclosure.

### BEST MODE

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

Meanwhile, an image display device described in this specification is, for example, an intelligent image display device having a computer supporting function in addition to a broadcast reception function, wherein an Internet function may be added while the broadcast reception function is devotedly performed, whereby an interface that is more conveniently used, such as a handwriting type input device, a touchscreen, or a space remote control, may be provided. In addition, the image display device may be connected to the Internet or a computer through support of a wired or wireless Internet function, whereby various functions, such as e-mail, web browsing, banking, or gaming, may be executed. For such various functions, a standardized general-purpose OS may be used.

In the image display device described in the present disclosure, therefore, various applications may be freely added or deleted, for example, on a general-purpose OS kernel, whereby various user friendly functions may be executed. More specifically, the image display device may be a network TV, an Hbb TV, or a smart TV, and is applicable to a smartphone depending on circumstances.

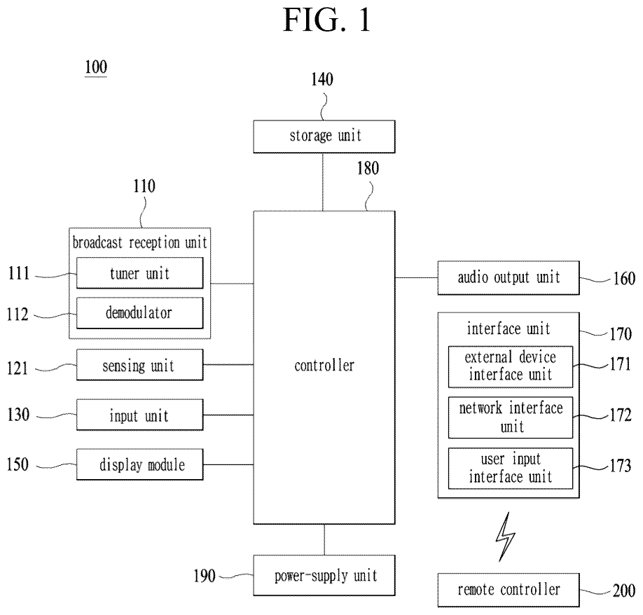

FIG. 1 is a block diagram illustrating components of a display device 100. The display device 100 may include a broadcast reception unit 110, an external device interface unit 171, a network interface unit 172, a storage unit 140, a user input interface unit 173, an input unit 130, a controller 180, a display module 150, an audio output unit 160, and/or a power supply unit 190.

The broadcast reception unit 110 may include a tuner unit 111 and a demodulation unit 112.

Unlike the figure, on the other hand, the display device 100 may include only the external device interface unit 171 and the network interface unit 172, among the broadcast reception unit 110, the external device interface unit 171, and the network interface unit 172. That is, the display device 100 may not include the broadcast reception unit 110.

The tuner unit 111 may select a broadcast signal corresponding to a channel selected by a user or any one of all pre-stored channels, among broadcast signals received through an antenna (not shown) or a cable (not shown). The tuner unit 111 may convert the selected broadcast signal into an intermediate frequency signal or a baseband video or audio signal.

For example, when the selected broadcast signal is a digital broadcast signal, the tuner unit 111 may convert the broadcast signal into a digital IF (DIF) signal, and when the selected broadcast signal is an analog broadcast signal, the tuner unit 111 may convert the broadcast signal into an analog baseband video or audio (CVBS/SIF) signal. That is, the tuner unit 111 may process the digital broadcast signal or the analog broadcast signal. The analog baseband video or audio (CVBS/SIF) signal output from the tuner unit 111 may be directly input to the controller 180.

Meanwhile, the tuner unit 111 may sequentially select broadcast signals of all broadcast channels stored through a channel memory function, among received broadcast signals, and may convert each of the selected broadcast signals into an intermediate frequency signal or a baseband video or audio signal.

Meanwhile, the tuner unit 111 may include a plurality of tuners in order to receive broadcast signals of a plurality of channels. Alternatively, a single tuner may simultaneously receive broadcast signals of a plurality of channels.

The demodulation unit 112 may receive the digital IF (DIF) signal converted by the tuner unit 111, and may perform demodulation. After performing demodulation and channel decryption, the demodulation unit 112 may output a stream signal (TS). At this time, the stream signal may be a multiplexed image, audio, or data signal.

The stream signal output from the demodulation unit 112 may be input to the controller 180. After performing demultiplexing and image/audio signal processing, the controller 180 may output an image through the display module 150, and may output audio through the audio output unit 160.

The sensing unit 120 is a device configured to sense change inside or outside the display device 100. For example, the sensing unit 120 may include at least one of a proximity sensor, an illumination sensor, a touch sensor, an infrared (IR) sensor, an ultrasonic sensor, an optical sensor (e.g. a camera), an audio sensor (e.g. a microphone), a battery gauge, and an environmental sensor (e.g. a hygrometer or a thermometer).

The controller 180 may check the state of the display device 100 based on information collected by the sensing unit, and when a problem occurs, may inform a user of the same or may solve the problem, whereby the controller may perform control such that the display device is maintained in the best state.

In addition, the controller may differently control the content, quality, and size of an image provided to the display module 150 based on a viewer or ambient light sensed by the sensing unit in order to provide the optimum viewing environment. With progress of a smart TV, a large number of functions have been loaded in the display device, and the sensing unit 20 has also been increased in number.

The input unit 130 may be provided at one side of a main body of the display device 100. For example, the input unit 130 may include a touchpad or a physical button. The input unit 130 may receive various user commands related to the operation of the display device 100, and may transmit control signals corresponding to the received commands to the controller 180.

With a decrease in size of a bezel of the display device 100, many display devices 100 have been configured such that the number of physical button type input units 130 exposed to the outside is minimized in recent years. Instead, a minimum number of physical buttons is located at the rear surface or the side surface of the display device, and the display device may receive user input through the touchpad or the user input interface unit 173, a description of which will follow, using a remote controller 200.

The storage unit 140 may store programs for signal processing and control in the controller 180, and may store a processed image, audio, or data signal. For example, the storage unit 140 may store application programs designed to execute various tasks that can be processed by the controller 180, and may selectively provide some of the stored application programs in response to request of the controller 180.

Programs stored in the storage unit 140 are not particularly restricted as long as the programs can be executed by the controller 180. The storage unit 140 may temporarily store an image, audio, or data signal received from an external device through the external device interface unit 171. The storage unit 140 may store information about a predetermined broadcast channel through a channel memory function, such as a channel map.

FIG. 1 shows an embodiment in which the storage unit 140 and the controller 180 are separately provided; however, the present disclosure is not limited thereto. The storage unit 140 may be included in the controller 180.

The storage unit 140 may include at least one of a volatile memory (e.g. DRAM, SRAM, or SDRAM), a nonvolatile memory (e.g. flash memory), a hard disk drive (HDD), and a solid-state drive (SSD).

The display module 150 may convert an image signal, a data signal, an OSD signal, and a control signal processed by the controller 180 or an image signal, a data signal, and a control signal received from the interface unit 171 to generate a driving signal. The display module 150 may include a display panel 181 having a plurality of pixels.

Each of the plurality of pixels in the display panel may include RGB subpixels. Alternatively, each of the plurality of pixels in the display panel may include RGBW subpixels. The display module 150 may convert an image signal, a data signal, an OSD signal, and a control signal processed by the controller 180 to generate a driving signal for the plurality of pixels.

A plasma display panel (PDP), a liquid crystal display (LCD), an organic light-emitting diode (OLED), or a flexible display may be used as the display module 150, and a 3D display may also be used. The 3D display 130 may be classified as a non-glasses type display or a glasses type display.

The display device includes a display module, which occupies a major portion of the front surface thereof, and a case configured to cover the rear surface and the side surface of the display module, the case being configured to package the display module.

In recent years, the display device 100 has used a flexible display module 150, such as light-emitting diodes (LED) or organic light-emitting diodes (OLED), in order to implement a curved screen.

Light is supplied to an LCD, which was mainly used conventionally, through a backlight unit, since the LCD is not self-emissive. The backlight unit is a device that supplies light emitted from a light source to a liquid crystal uniformly located in front thereof. As the backlight unit has been gradually thinned, a thin LCD has been implemented. However, it is difficult to implement the backlight unit using a flexible material. If the backlight unit is curved, it is difficult to supply uniform light to the liquid crystal, whereby the brightness of a screen is changed.

In contrast, the LED or the OLED may be implemented so as to be curved, since an element constituting each pixel is self-emissive, and therefore no backlight unit is used. In addition, since each element is self-emissive, the brightness of the element is not affected even though the positional relationship between adjacent elements is changed, and therefore it is possible to implement a curved display module 150 using the LED or the OLED.

An organic light-emitting diode (OLED) panel appeared in earnest in mid 2010 and has rapidly replaced the LCD in the small- or medium-sized display market. The OLED is a display manufactured using a self-emissive phenomenon of an organic compound in which the organic compound emits light when current flows in the organic compound. The response time of the OLED is shorter than the response time of the LCD, and therefore afterimages hardly appear when video is implemented.

The OLED is an emissive display product that uses three fluorescent organic compounds having a self-emissive function, such as red, green, and blue fluorescent organic compounds and that uses a phenomenon in which electrons injected at a negative electrode and a positive electrode and particles having positive charges are combined in the organic compounds to emit light, and therefore a backlight unit, which deteriorates color, is not needed.

A light-emitting diode (LED) panel is based on technology of using one LED element as one pixel. Since it is possible to reduce the size of the LED element, compared to a conventional device, it is possible to implement a curved display module 150. The conventional device, which is called an LED TV, uses the LED as a light source of a backlight unit that supplies light to the LCD, and therefore the LED does not constitute a screen.

The display module includes a display panel and a coupling magnet, a first power supply unit, and a first signal module located at a rear surface of the display panel. The display panel may include a plurality of pixels R, G, and B. The plurality of pixels R, G, and B may be formed at intersections between a plurality of data lines and a plurality of gate lines. The plurality of pixels R, G, and B may be disposed or arranged in a matrix form.

For example, the plurality of pixels R, G, and B may include a red subpixel ‘R’, a green subpixel ‘G’, and a blue subpixel ‘B’. The plurality of pixels R, G, and B may include a white subpixel ‘W’.

The side of the display module 150 on which a picture is displayed may be referred to as a front side or a front surface. When the display module 150 displays the picture, the side of the display module 150 from which the picture cannot be viewed may be referred to as a rear side or a rear surface. Meanwhile, the display module 150 may be constituted by a touchscreen, whereby an input device may also be used in addition to an output device.

The audio output unit 160 receives an audio signal processed by the controller 180 and outputs the same as audio.

The interface unit 170 serves as a path to various kinds of external devices connected to the display device 100. The interface unit may include a wireless system using an antenna as well as a wired system configured to transmit and receive data through a cable.

The interface unit 170 may include at least one of a wired/wireless headset port, an external charger port, a wired/wireless data port, a memory card port, a port for connection with a device having an identification module, an audio input/output (I/O) port, a video input/output (I/O) port, and an earphone port.

The broadcast reception unit 110 may be included as an example of the wireless system, and a mobile communication signal, a short-range communication signal, and a wireless Internet signal as well as a broadcast signal may be included.

The external device interface unit 171 may transmit or receive data to or from a connected external device. To this end, the external device interface unit 171 may include an A/V input and output unit (not shown).

The external device interface unit 171 may be connected to an external device, such as a digital versatile disc (DVD) player, a Blu-ray player, a game console, a camera, a camcorder, a computer (laptop computer), or a set-top box, in wired/wireless manner, and may perform input/output operation for the external device.

In addition, the external device interface unit 171 may establish a communication network with various remote controllers 200 in order to receive a control signal related to the operation of the display device 100 from each remote controller 200 or to transmit data related to the operation of the display device 100 to each remote controller 200.

The external device interface unit 171 may include a wireless communication unit (not shown) for short-range wireless communication with another electronic device. The external device interface unit 171 may exchange data with a mobile terminal adjacent thereto through the wireless communication unit (not shown). Particularly, in a mirroring mode, the external device interface unit 171 may receive device information, information of an application that is executed, and an image of the application from the mobile terminal.

The network interface unit 172 may provide an interface for connection of the display device 100 with a wired/wireless network including the Internet. For example, the network interface unit 172 may receive content or data provided by an Internet or content provider or a network operator through the network. Meanwhile, the network interface unit 172 may include a communication module (not shown) for connection with the wired/wireless network.

The external device interface unit 171 and/or the network interface unit 172 may include a communication module for short-range communication, such as Wi-Fi, Bluetooth, Bluetooth Low Energy (BLE), ZigBee, or Near Field Communication (NFC), or a communication module for cellular communication, such as Long-Term Evolution (LTE), LTE Advance (LTE-A), Code Division Multiple Access (CDMA), Wideband CDMA (WCDMA), Universal Mobile Telecommunications System (UMTS), or Wireless Broadband (WiBro).

The user input interface unit 173 may transmit a user input signal to the controller 180, or may transmit a signal from the controller 180 to a user. For example, the user input interface unit may transmit/receive a user input signal, such as power on/off, channel selection, or screen setting, to/from the remote controller 200, may transmit a user input signal, such as a power key, a channel key, a volume key, or a setting value, input from a local key (not shown) to the controller 180, may transmit a user input signal input from a sensor unit (not shown) configured to sense user gesture to the controller 180, or may transmit a signal from the controller 180 to the sensor unit.

The controller 180 may include at least one processor, and may control the overall operation of the display device 100 using the processor included therein. Here, the processor may be a general processor, such as a central processing unit (CPU). Of course, the processor may be a dedicated device, such as an ASIC, or another hardware-based processor.

The controller 180 may demultiplex a stream input through the tuner unit 111, the demodulation unit 112, the external device interface unit 171, or the network interface unit 172, or may process demultiplexed signals to generate and output a signal for image or audio output.

An image signal processed by the controller 180 may be input to the display module 150, which may display an image corresponding to the image signal. In addition, the image signal processed by the controller 180 may be input to an external output device through the external device interface unit 171.

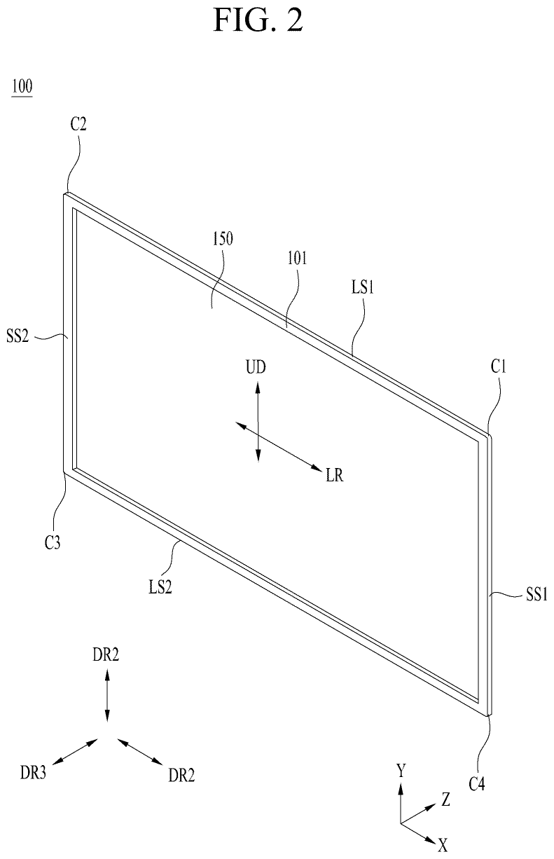

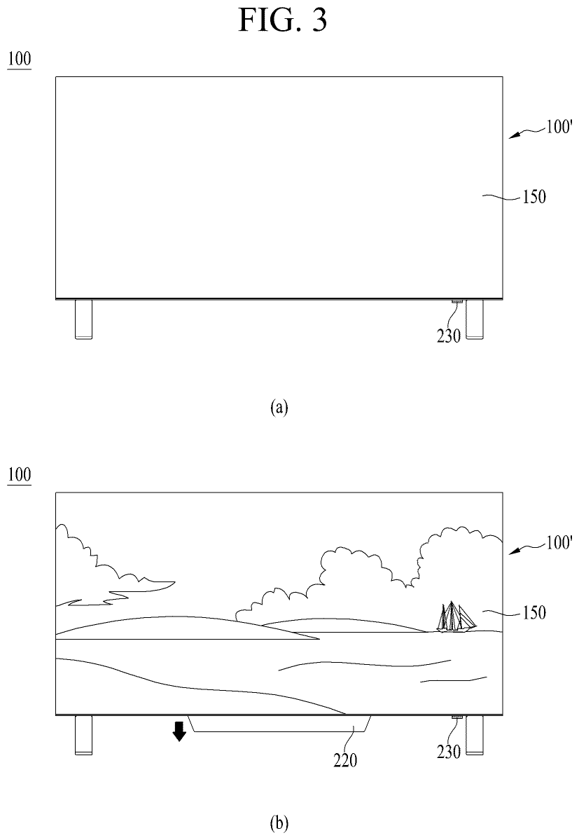

An audio signal processed by the controller 180 may be output through the audio output unit 160. In addition, the audio signal processed by the controller 180 may be input to an external output device through the external device interface unit 171. Although not shown in FIG. 2, the controller 180 may include a demultiplexing unit and an image processing unit, which will be described below with reference to FIG. 3.

Further, the controller 180 may control the overall operation of the display device 100. For example, the controller 180 may control the tuner unit 111 such that a broadcast corresponding to a channel selected by a user or a pre-stored channel is tuned.

In addition, the controller 180 may control the display device 100 according to a user command input through the user input interface unit 173 or an internal program. Meanwhile, the controller 180 may control the display module 150 to display an image. At this time, the image displayed on the display module 150 may be a still image or video, or may be a 2D image or a 3D image.

Meanwhile, the controller 180 may perform control such that a predetermined 2D object is displayed in an image displayed on the display module 150. For example, the object may be at least one of a connected web screen (newspaper or magazine), an electronic program guide (EPG), various menus, a widget, an icon, a still image, video, and text.

Meanwhile, the controller 180 may modulate and/or demodulate a signal using an amplitude shift keying (ASK) method. Here, the amplitude shift keying (ASK) method may be a method of changing the amplitude of a carrier depending on a data value to modulate a signal or restoring an analog signal to a digital data value depending on the amplitude of a carrier.

For example, the controller 180 may modulate an image signal using the amplitude shift keying (ASK) method, and may transmit the modulated image signal through a wireless communication module.

For example, the controller 180 may demodulate and process an image signal received through the wireless communication module using the amplitude shift keying (ASK) method.

As a result, the display device 100 may easily transmit and receive a signal to and from another image display device disposed adjacent thereto without using a unique identifier, such as a media access control (MAC) address, or a complicated communication protocol, such as TCP/IP.

Meanwhile, the display device 100 may further include a photographing unit (not shown). The photographing unit may photograph a user. The photographing unit may be implemented by one camera; however, the present disclosure is not limited thereto. The photographing unit may be implemented by a plurality of cameras. Meanwhile, the photographing unit may be embedded in the display device 100 above the display module 150, or may be separately disposed. Image information photographed by the photographing unit may be input to the controller 180.

The controller 180 may recognize the location of a user based on an image captured by the photographing unit. For example, the controller 180 may recognize the distance between the user and the display device 100 (z-axis coordinate). Further, the controller 180 may recognize an x-axis coordinate and a y-axis coordinate in the display module 150 corresponding to the location of the user.

The controller 180 may sense user gesture based on the image captured by the photographing unit, a signal sensed by the sensor unit, or a combination thereof.

The power supply unit 190 may supply power to the components of the display device 100. In particular, the power supply unit may supply power to the controller 180, which may be implemented in the form of a system on chip (SOC), the display module 150 for image display, and the audio output unit 160 for audio output.

Specifically, the power supply unit 190 may include an AC/DC converter (not shown) configured to convert AC power into DC power and a DC/DC converter (not shown) configured to convert the level of the DC power.

Meanwhile, the power supply unit 190 serves to distribute power supplied from the outside to the respective components of the display device. The power supply unit 190 may be directly connected to an external power supply in order to supply AC power, or may include a battery so as to be used by charging.

In the former case, a cable is used, and the power supply unit is difficult to move or the movement range of the power supply unit is limited. In the latter case, the power supply unit is free to move, but the weight of the power supply unit is increased in proportion to the weight of the battery, the volume of the power supply unit is increased, and, for charging, the power supply unit must be directly connected to a power cable or must be coupled to a charging holder (not shown) that supplies power for a predetermined time.

The charging holder may be connected to the display device through a terminal exposed to the outside, or the battery mounted in the power supply unit may be charged in a wireless manner when the power supply unit approaches the charging holder.

The remote controller 200 may transmit user input to the user input interface unit 173. To this end, the remote controller 200 may use Bluetooth communication, radio frequency (RF) communication, infrared radiation communication, ultra-wideband (UWB) communication, or ZigBee communication. In addition, the remote controller 200 may receive an image, audio, or data signal output from the user input interface unit 173 so as to be displayed thereon or audibly output therefrom.

Meanwhile, the display device 100 may be a stationary or movable digital broadcast receiver capable of receiving a digital broadcast.

Meanwhile, the block diagram of the display device 100 shown in FIG. 1 is for an embodiment of the present disclosure, and elements of the block diagram may be integrated, added, or omitted depending on specifications of an actually implemented display device 100.

That is, two or more elements may be integrated into one element, or one element may be divided into two or more elements, as needed. In addition, the function performed by each block is for describing the embodiment of the present disclosure, and the specific operations and components thereof do not limit the scope of rights of the present disclosure.

FIG. 2 is a front perspective view showing an example of the display device.

Referring to FIG. 2, the display device 100 may have a rectangular shape including a first long side LS1, a second long side LS2 opposite the first long side LS1, a first short side SS1 adjacent to the first long side LS1 and the second long side LS2, and a second short side SS2 opposite the first short side SS1.

Here, the area of the first short side SS1 may be referred to as a first side area, the area of the second short side SS2 may be referred to as a second side area opposite the first side area, the area of the first long side LS1 may be referred to as a third side area adjacent to the first side area and the second side area and located between the first side area and the second side area, and the area of the second long side LS2 may be referred to as a fourth side area adjacent to the first side area and the second side area, located between the first side area and the second side area, and opposite the third side area.

In addition, the lengths of the first and second long sides LS1 and LS2 are shown and described as being greater than the lengths of the first and second short sides SS1 and SS2, for convenience of description; however, the lengths of the first and second long sides LS1 and LS2 may be approximately equal to the lengths of the first and second short sides SS1 and SS2.

Also, in the following description, a first direction DR1 may be a direction parallel to the long sides LS1 and LS2 of the display device 100, and a second direction DR2 may be a direction parallel to the short sides SS1 and SS2 of the display device 100. A third direction DR3 may be a direction perpendicular to the first direction DR1 and/or the second direction DR2.

From a different point of view, the side of the display device 100 on which a picture is displayed may be referred to as a front side or a front surface. When the display device 100 displays the picture, the side of the display device 100 from which the picture cannot be viewed may be referred to as a rear side or a rear surface. When viewing the display device 100 from the front side or the front surface, the side of the first long side LS1 may be referred to as an upper side or an upper surface. In the same manner, the side of the second long side LS2 may be referred to as a lower side or a lower surface. In the same manner, the side of the first short side SS1 may be referred to as a right side or a right surface, and the side of the second short side SS2 may be referred to as a left side or a left surface.

In addition, the first long side LS1, the second long side LS2, the first short side SS1, and the second short side SS2 may be referred to edges 351 of the display device 100. In addition, points at which the first long side LS1, the second long side LS2, the first short side SS1, and the second short side SS2 are joined to each other may be referred to as corners. For example, a point at which the first long side LS1 and the first short side SS1 are joined to each other may be a first corner C1, a point at which the first long side LS1 and the second short side SS2 are joined to each other may be a second corner C2, a point at which the second short side SS2 and the second long side LS2 are joined to each other may be a third corner C3, and a point at which the second long side LS2 and the first short side SS1 are joined to each other may be a fourth corner C4.

Here, a direction from the first short side SS1 to the second short side SS2 or a direction from the second short side SS2 to the first short side SS1 may be referred to as a leftward-rightward direction LR. A direction from the first long side LS1 to the second long side LS2 or a direction from the second long side LS2 to the first long side LS1 may be referred to as a vertical direction UD.

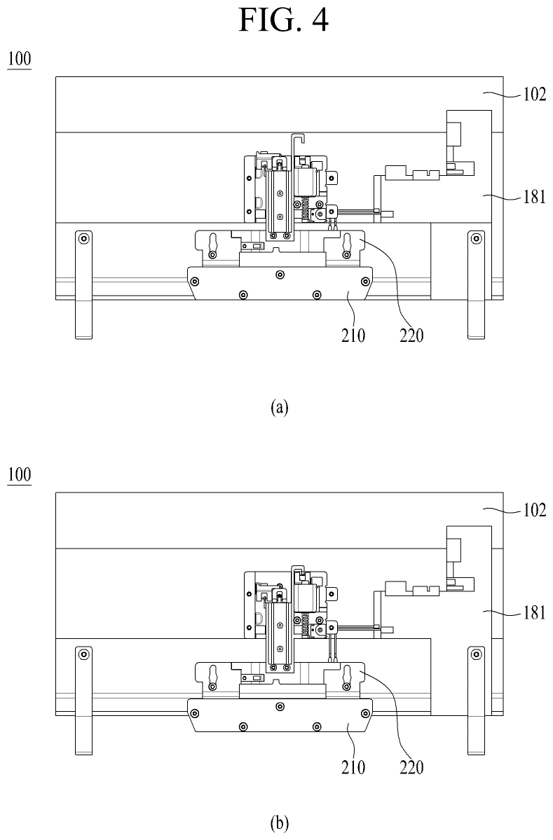

FIG. 3 and FIG. 4 are diagrams illustrating front and rear surfaces of a display device 100 according to the present disclosure in an OFF state and an ON state. The display device 100 according to the present disclosure may be used as a panel capable of implementing a slim design such as an OLED. There is a problem in that a wireless signal fails to reach an antenna 212 located on a rear surface when the display device 100 is mounted on a wall due to a thin thickness in a front-rear direction. In addition, a size of a bezel is small, and thus there is not enough space to dispose the antenna 212 around a display body 100′.

Accordingly, in the display device 100 having a thin bezel-less thickness, a separate moving bracket may be used to dispose the antenna 212. The moving bracket 210 is positioned in a rear surface direction when a display module 150 is in an OFF state as shown in FIG. 3 (a). Yet, when the display module 150 is switched to an ON state, the moving bracket 210 hidden in a display rear surface is exposed from a bottom side of the display body 100′.

By disposing the antenna 212 on the moving bracket 210, the antenna 212 may be exposed in a front direction so that various types of wireless communication can be smoothly performed during the use of the display device 100.

If the moving bracket 210 always protrudes from the bottom as shown in FIG. 3 (b), there is a problem of damaging the bezel-less design of the display device 100, so if necessary, it may be moved downward to be seen from the front side only when using the display device 100.

Referring to FIG. 4, a cover bottom and a printed circuit board seated on a rear surface thereof and controlling the display device 100 are illustrated in a state in which a back cover forming a rear exterior is removed. Also, a moving bracket 210 located under the cover bottom and a driving unit 220 for moving the moving bracket 210 up and down are illustrated.

A cable connecting the driving unit 220 and the printed circuit board to control a motor 221 located in the driving unit 220 and transmit and receive wireless signals through the antenna 212 on which the moving bracket 210 is mounted may be included.

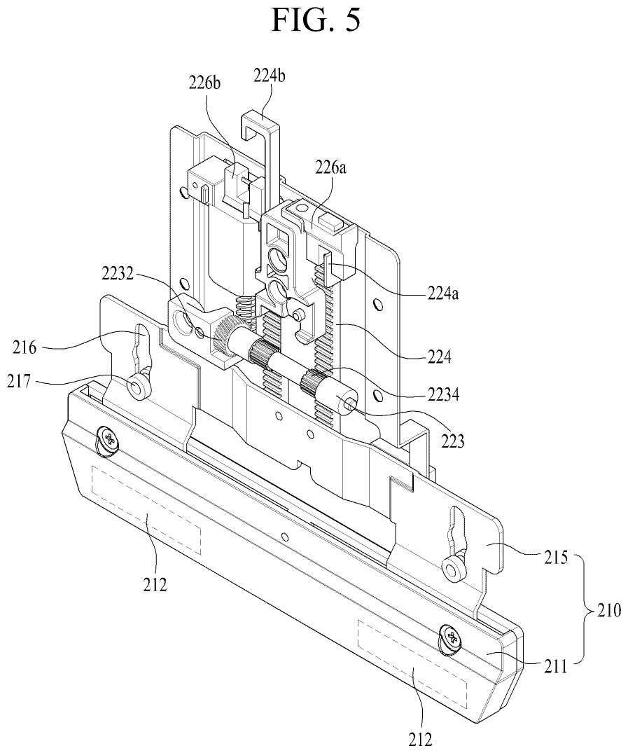

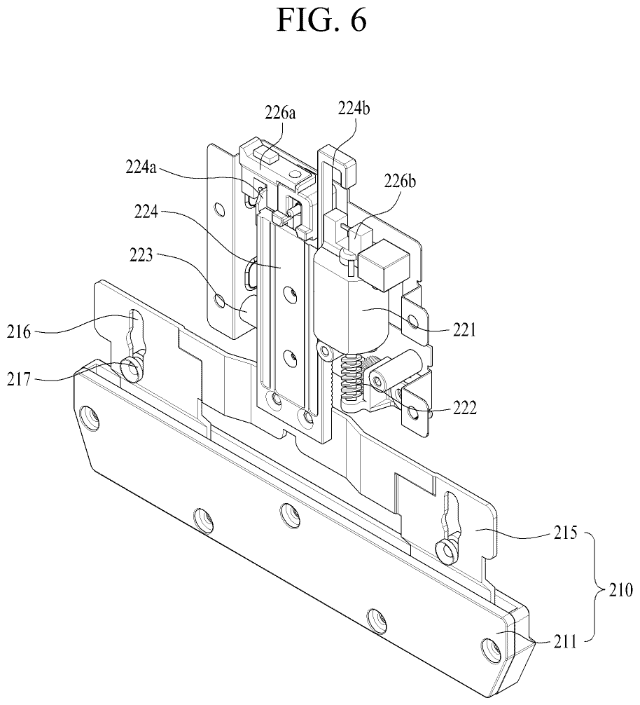

FIG. 5 is a front perspective diagram illustrating a first state of the driving unit 220 and the moving bracket 210 of the display device 100 of the present disclosure, and FIG. 6 is a rear perspective diagram illustrating a first state of the driving unit 220 and the moving bracket 210 of the display device 100 of the present disclosure.

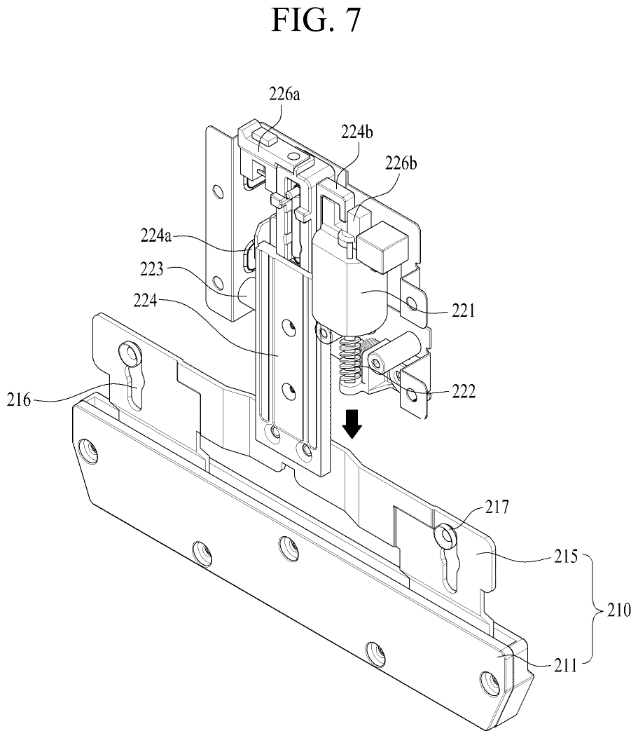

FIG. 7 is a rear perspective diagram illustrating a second state of the driving unit 220 and the moving bracket 210 of the display device 100 according to the present disclosure.

The driving unit 220 includes a motor 221 that provides rotational force and a rack gear 224 that moves in a vertical direction by receiving the rotational force of the motor 221 and is fastened to the moving bracket 210. The rack gear 224 is disposed long in the vertical direction for vertical movement, and a gear part including a plurality of teeth is formed on a surface thereof. The teeth may extend in a horizontal direction, and may be consecutively formed in the vertical direction.

In order to provide a driving force to the rack gear 224, the motor 221 may include a first gear 222 and the second gear 2232 may be disposed to be directly engaged with the rack gear 224. In this case, the motor 221 is disposed to rotate with an axis in a horizontal direction.

Yet, in this case, a vertical load of the moving bracket 210 is applied to the motor 221 so that the rotation of the motor 221 may be uneven, and in some cases, the motor 221 may be damaged. Therefore, since it is advantageous in terms of durability to dispose a shaft of the motor 221 in the vertical direction, as shown in FIG. 5, the motor 221 may be disposed in the vertical direction.

A shaft member 223 including a second gear 2232 that rotates in conjunction with the first gear 222 of the motor 221 and a third gear 2234 that rotates in conjunction with a gear part of the rack gear 224 may be provided to transmit the power of the motor 221 having the rotating shaft disposed in the vertical direction to the rack gear 224 disposed in the vertical direction.

The shaft member 223 may extend in a horizontal direction, the second gear 2232 may be disposed at one side of the shaft member 223, and the third gear 2234 may be disposed at the other side. Since the third gear 2234 rotates while being engaged with the teeth of the rack gear 224 extending in the horizontal direction, a spur gear including a plurality of teeth extending in the axial direction from the outside of a circumference may be used.

An axial direction of the rotational force may be changed to a vertical direction by using a bevel gear having a conical shape as the first gear 222 and the second gear 2232.

As shown in FIG. 6, a worm shaft in which spiral teeth are formed may be configured as the first gear 222, and a worm wheel in which teeth engaged with the teeth of the worm shaft are formed on an outer circumferential surface may be configured as the second gear 2232.

A rotational axis of the first gear 222 is vertical, a rotational axis of the second gear 2232 has a direction of a rotational force changed from a vertical direction to a horizontal direction, and the third gear 2234 is connected to the second gear 2232 through the shaft member 223 to rotate at the same time and move the rack gear 224 up and down.

The shaft member 223 may further include a stepped portion 2236 in order to configure the shaft member 223 to be disposed at a correct position without moving in the horizontal direction to maintain a fastened state with the first gear 222 and the rack gear 224.

A first stepped portion 2236 formed on both sides of the third gear 2234 is included. The first stepped portion 2236 is in contact with a second stepped portion 2236 formed in the rack fear 224 or a horizontal end portion of the rack gear 224 and limits a horizontal movement of the shaft member 223.

In the rack gear 224 of the present embodiment, a pair of gear parts may be provided to be spaced apart from each other in a horizontal direction, and a pair of third gears 2234 may be provided correspondingly. A space between a pair of the gear parts of the rack gear 224 may protrude to be positioned between a pair of the third gears 2234.

The moving bracket 210 coupled to a lower end portion of the rack gear 224 may further include a vertical guide 216 that moves in a vertical direction according to the movement of the rack gear 224 and is fastened to a guide projection 217 formed on a rear surface of the cover bottom as shown in FIG. 4 to prevent distortion.

The vertical guide 216 may include an opening extending in the vertical direction, and may include a portion having a partially large width so that the guide projection 217 may be inserted thereinto. An end portion of the guide projection 217 may have a nail shape with an expanded diameter, and a width of the vertical guide 216 in the first state and the second state is smaller than the end portion of the guide projection 217, so that the guide projection 217 and the vertical guide 216 do not separate from each other.

A lower end portion 211 of the moving bracket 210 is selectively exposed to the front, and unlike an upper portion 215 of the moving bracket 210 coupled to the rack gear 224, a cover forming an external appearance may be further included.

The antenna 212 may be mounted on the lower end portion 211 of the moving bracket 210, and the lower end portion 211 may be made of a non-metallic material so as not to interfere with a signal of the antenna 212.

The moving bracket 210 moves up and down between a first position (i.e., a state where the moving bracket 210 is completely moved upward) and a second position (i.e., a state where the moving bracket 210 is completely moved downward). A position sensor 226a and 226b may be further included to determine a position of the moving bracket 210.

The position sensor 226a and 226b is a device that detects a position of a specific object in a sensing area of a sensor and may form a switch type. A first position sensor 226a may be turned on when the moving bracket 210 is at the first position, and a second position sensor 226b may be positioned in the driving unit 220 to be turned on when the moving bracket 210 is at the second position.

Protrusions 224a and 224b for turning on/off the first position sensor 226a and the second position sensor 226b, respectively, may be located on the rack gear 224. A single protrusion may move between the first position sensor 226a and the second position sensor 226b. As shown in FIG. 6, a first protrusion 224a for turning on the first position sensor 226a and a second protrusion 224b for turning on the second position sensor 226b may be included.

At the first position, the first protrusion 224a turns on the first position sensor 226a (FIG. 6). The second protrusion 224b turns on the second position sensor 226b at the second position where the moving bracket 210 and the rack gear 224 are moved downward (FIG. 7).

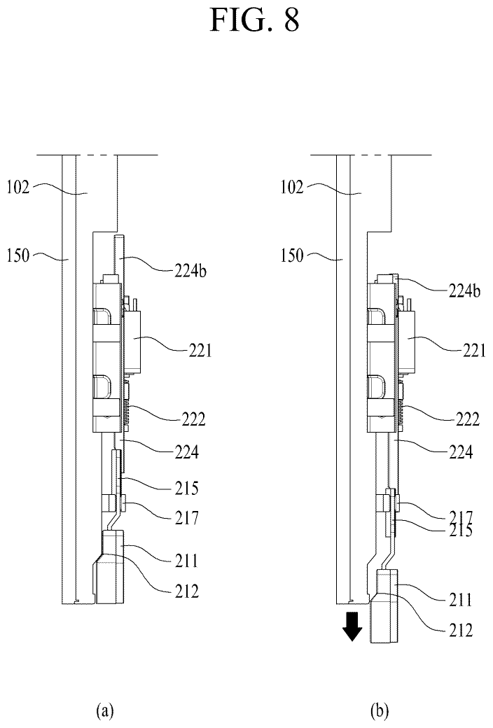

FIG. 8 is a side diagram illustrating a lower portion of the display device 100 of the present disclosure. (a) illustrates that the moving bracket 210 is at the first position, and (b) illustrates that the moving bracket 210 is at the second position.

Since the driving unit 220 includes a member having a prescribed volume, such as a motor 221 or the like, the driving unit 220 is projected from the cover bottom in a rear surface direction. An ultra-small motor 221 of which output is not large may be used by minimizing the weight of the moving bracket 210.

In the present embodiment, the motor 221 may use a small motor 221 having a diameter of Ø10 (10 mm), and the thickness of the driving unit 220 may be implemented as thin as about 15.5 mm.

The moving bracket 210 may be disposed as close as possible in the front direction when exposed to the front surface, thereby providing a continuous appearance with the display module 150.

Considering the thickness of the driving unit 220, an upper part of the moving bracket 210 may be bent so that a lower part protrudes in the front direction, and the lower part of the moving bracket 210 may be configured to have irregularities corresponding to the irregularities on the surface of the cover bottom to implement the design as thin as possible.

In the present embodiment, the front surface of the moving bracket 210 may be curved to correspond to the irregularities formed in the lower part of the cover bottom, and the rear surface may form a uniform surface.

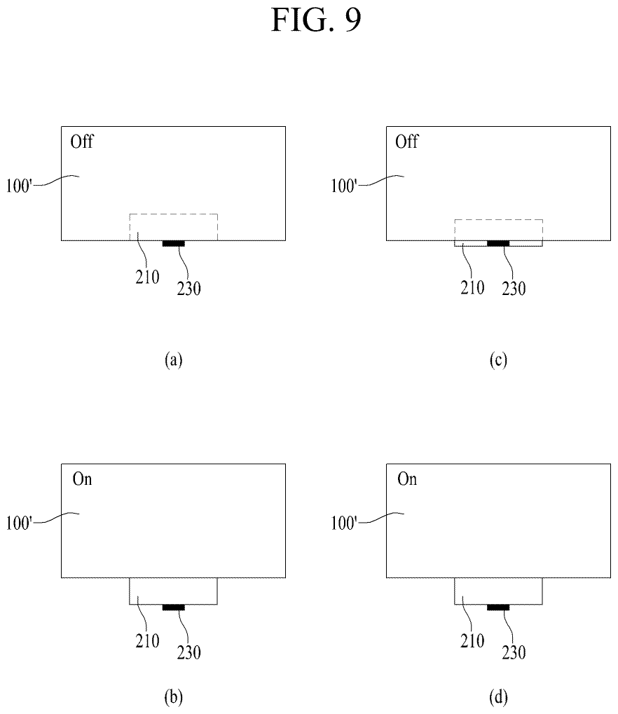

FIG. 9 is a diagram illustrating a disposition example of the IR sensor 230 and the moving bracket 210 of the present disclosure.

The antenna 212 may be mounted on the moving bracket 210, but the display device 100 may be able to detect an ON/OFF signal of a remote controller for turning on the display device 100 in the OFF state.

The IR sensor 230 that detects the signal of the remote controller may be provided separately from the moving bracket 210 as shown in FIG. 3, and may always be exposed in the front direction.

Also, as shown in FIG. 9, it may be coupled to the moving bracket 210. Instead, it may be positioned at a lower end portion of the moving bracket 210 so as to be exposed in the front direction even when the display device 100 is turned off.

As shown in (a) and (b) of FIG. 9, only the IR sensor 230 may be coupled to the lower end of the moving bracket 210 so as to be exposed, or the lower part of the moving bracket 210 may be partially exposed through the lower part even at the first position.

When an ON signal of the display device 100 is detected through the remote controller, the controller may move the moving bracket from the first position to the second position to expose the antenna 212 and may transmit/receive image data or transmit an audio signal through wireless communication using the exposed antenna 212. As described above, the display device 100 of the present disclosure may provide the bezel-less, slim-designed display device 100.

The display device 100 of the present disclosure may maintain a clean appearance in normal times by selectively exposing components necessary for viewing the display device 100 in the front direction, such as the antenna 212 or the speaker.

The above detailed description should not be construed as being limitative in all terms, but should be considered as being illustrative. The scope of the present disclosure should be determined by reasonable analysis of the accompanying claims, and all changes in the equivalent range of the present disclosure are included in the scope of the present disclosure.

1. A display device, comprising:
a display module outputting an image;
a cover bottom covering a rear surface of the display module;
a moving bracket positioned on the rear surface of the cover bottom and having a variable size of an area exposed under the display module;
an antenna module mounted on the moving bracket;
a driving unit driving the moving bracket in a vertical direction, the driving unit comprising:
a motor providing a rotational force; and
a rack gear moving in the vertical direction by receiving the rotational force of the motor and fastened to the moving bracket,
an IR sensor sensing a remote control signal for turning on/off the display module; and
a controller configured to drive the motor to move downward the moving bracket from an upper position to lower position when the display module turning on,
wherein the IR sensor is disposed at a lower end portion of the moving bracket so as to be exposed in a front direction in the upper position and the lower position; and,
wherein the antenna is located on the back of the display module when the moving bracket is in the upper position, and is located below the display module when the moving bracket is in the lower position.

2. The display device of claim 1, wherein an axis of the motor is vertically disposed and wherein the driving unit comprises
a first gear coupled to a rotational shaft of the motor;
a second gear rotating by engaging with the first gear and having a horizontal direction as an axis; and
a third gear rotating about the horizontal direction based on rotation of the second gear and rotating by engaging with the rack gear.

3. The display device of claim 2, wherein the first gear is a worm shaft and wherein the second gear is a worm gear.

4. The display device of claim 2, comprising a shaft member having the second gear positioned at one end portion thereof and the third gear positioned at the other side thereof,
wherein a first stepped portion is formed at both sides of the third gear and
wherein the rack gear comprises a second stepped portion having a shape related to a stepped portion of the third gear.

5. The display device of claim 2, wherein the rack gear comprises a pair of gear parts spaced apart from each other in the horizontal direction and wherein a pair of the third gears are provided to correspond to positions of the gear parts, respectively.

6. The display device of claim 1, wherein the rack gear is coupled to a center of the moving bracket and wherein the display device further comprises vertical guides positioned at both sides of the moving bracket, respectively.

7-8. (canceled)

9. The display device of claim 1, wherein the moving bracket moves between a first position and a second position, wherein the moving bracket further comprises a position sensor generating a braking signal by detecting whether at least one of the first position or the second position is reached, and wherein the controller stops driving the motor in response to the braking signal of the position sensor.

10. The display device of claim 1, wherein a diameter of the motor is equal to or smaller than 10 mm.

11. (canceled)

12. The display device of claim 1, further comprising a printed circuit board located on the back of the cover bottom; and
a cable connecting the printed circuit board to the IR sensor, and the antenna.
